(19) United States
(12) Patent Application Publication
(10) Pub. No.: US 2026/0051853 A1
(43) Pub. Date: Feb. 19, 2026

(54) POWER MANAGEMENT CIRCUIT OPERABLE WITH A REDUCED VOLTAGE RANGE

(71) Applicant: Qorvo US, Inc., Greensboro, NC (US)

(72) Inventor: Nadim Khlat, Ceret (FR)

(21) Appl. No.: 19/226,326

(22) Filed: Jun. 3, 2025

Related U.S. Application Data
(60) Provisional application No. 63/666,792, filed on Jul. 2, 2024.

(51) Int. Cl. H03F 1/02; H03F 3/24

(52) U.S. Cl. CPC H03F 1/0233; H03F 3/245; H03F 2200/451

(57) ABSTRACT

A power management circuit operable with a reduced voltage range is provided. Herein, a power management integrated circuit (PMIC) is configured to generate an envelope tracking (ET) voltage whereby a power amplifier circuit can amplify a radio frequency (RF) signal for transmission. Specifically, the power management circuit can be configured according to various embodiments to achieve the reduced voltage range by applying a combination of load modulation and supply modulation across a larger voltage range (e.g., a peak-to-peak voltage range) required for amplifying the RF signal between a peak-to-peak power range (a.k.a. minimum to maximum power range). By dynamically reducing the voltage range of the RF signal, the PMIC and/or the power amplifier circuit in the power management circuit can operate with an improved efficiency to thereby provide an improvement in the user experience.

### RELATED APPLICATIONS

This application claims the benefit of U.S. provisional patent application Ser. No. 63/666,792, filed on Jul. 2, 2024, the disclosure of which is hereby incorporated herein by reference in its entirety.

### FIELD OF THE DISCLOSURE

The present disclosure is related to a power management circuit operable with a reduced voltage range (e.g., a peak-to-peak voltage range).

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by such advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit(s), a power amplifier circuit(s), and a power management circuit(s). Specifically, the transceiver circuit(s) modulates the transmission signal to an intended transmission frequency, the power amplifier circuit(s) amplifies the transmission signal to the desired power level, and the power management circuit(s) supplies an envelope tracking (ET) to the power amplifier circuit(s). Understandably, to achieve the best possible efficiency and performance, the power management circuit(s) must adapt the ET voltage in accordance with a modulation bandwidth of the transmission signal.

### SUMMARY

Embodiments of the disclosure relate to a power management circuit operable with a reduced voltage range. Herein, a power management integrated circuit (PMIC) is configured to generate an envelope tracking (ET) voltage whereby a power amplifier circuit can amplify a radio frequency (RF) signal for transmission. Specifically, the power management circuit can be configured according to various embodiments to achieve the reduced voltage range by applying a combination of load modulation and supply modulation across a larger voltage range (e.g., a peak-to-peak voltage range) required for amplifying the RF signal between a peak-to-peak power range (a.k.a. minimum to maximum power range). By dynamically reducing the voltage range of the RF signal, the PMIC and/or the power amplifier circuit in the power management circuit can operate with an improved efficiency to thereby provide an improvement in the user experience.

In one aspect, a power management circuit is provided. The power management circuit includes a power amplifier circuit. The power amplifier circuit is coupled to a voltage output. The power amplifier circuit is configured to amplify an RF signal from an input power to an output power based on a modulated voltage. The power management circuit also includes a PMIC. The PMIC includes a voltage modulation circuit. The voltage modulation circuit is configured to generate the modulated voltage at the voltage output in accordance with a modulated target voltage. The PMIC also includes a control circuit. The control circuit is configured to determine a first power threshold that is lower than a max power threshold of the RF signal. The control circuit is also configured to cause the voltage modulation circuit to generate the modulated voltage based on a supply modulation when a power level of the RF signal is higher than or equal to the first power threshold. The control circuit is also configured to cause the voltage modulation circuit to generate the modulated voltage based on a load modulation when the power level of the RF signal is below the first power threshold.

In another aspect, a wireless device is provided. The wireless device includes a power management circuit. The power management circuit includes a power amplifier circuit. The power amplifier circuit is coupled to a voltage output. The power amplifier circuit is configured to amplify an RF signal from an input power to an output power based on a modulated voltage. The power management circuit also includes a PMIC. The PMIC includes a voltage modulation circuit. The voltage modulation circuit is configured to generate the modulated voltage at the voltage output in accordance with a modulated target voltage. The PMIC also includes a control circuit. The control circuit is configured to determine a first power threshold that is lower than a max power threshold of the RF signal. The control circuit is also configured to cause the voltage modulation circuit to generate the modulated voltage based on a supply modulation when a power level of the RF signal is higher than or equal to the first power threshold. The control circuit is also configured to cause the voltage modulation circuit to generate the modulated voltage based on a load modulation when the power level of the RF signal is below the first power threshold.

In another aspect, a method for operating a power management circuit with a reduced voltage range is provided. The method includes amplifying an RF signal from an input power to an output power based on a modulated voltage. The method also includes generating the modulated voltage in accordance with a modulated target voltage. The method also includes determining a first power threshold that is lower than a max power threshold of the RF signal. The method also includes generating the modulated voltage based on a supply modulation when a power level of the RF signal is higher than or equal to the first power threshold. The method also includes generating the modulated voltage based on a load modulation when the power level of the RF signal is below the first power threshold.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary existing power management circuit wherein a power management integrated circuit (PMIC) can generate a modulated voltage (e.g., an envelope tracking voltage) in accordance with a modulated target voltage for amplifying a radio frequency (RF) signal across a peak-to-peak power range (a.k.a. minimum to maximum power range);

FIG. 1B is a diagram providing an exemplary illustration as to how the existing power management circuit of FIG. 1A is operable to generate the modulated voltage for amplifying the RF signal across the peak-to-peak power range;

FIG. 2 is a schematic diagram of an exemplary power management circuit wherein a PMIC can be configured according to various embodiments of the present disclosure to reduce a peak-to-peak range of the modulated voltage in FIG. 1 such that the power management circuit can achieve an improved operating efficiency over the existing power management circuit of FIG. 1A when amplifying an RF signal across a peak-to-peak power range;

FIGS. 3-6 are diagrams providing exemplary illustrations as to how the power management circuit of FIG. 2 can reduce the peak-to-peak range of the modulated voltage across the peak-to-peak power range of the RF signal;

FIG. 7 is a schematic diagram of an exemplary communication device wherein the higher-bandwidth power management circuit of FIG. 2 can be provided; and

FIG. 8 is a flowchart of an exemplary process for operating the power management circuit of FIG. 2.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to a power management circuit operable with a reduced voltage range. Herein, a power management integrated circuit (PMIC) is configured to generate an envelope tracking (ET) voltage whereby a power amplifier circuit can amplify a radio frequency (RF) signal for transmission. Specifically, the power management circuit can be configured according to various embodiments to achieve the reduced voltage range by applying a combination of load modulation and supply modulation across a larger voltage range (e.g., a peak-to-peak voltage range) required for amplifying the RF signal between a peak-to-peak power range (a.k.a. minimum to maximum power range). By dynamically reducing the voltage range of the RF signal, the PMIC and/or the power amplifier circuit in the power management circuit can operate with an improved efficiency to thereby provide an improvement in the user experience.

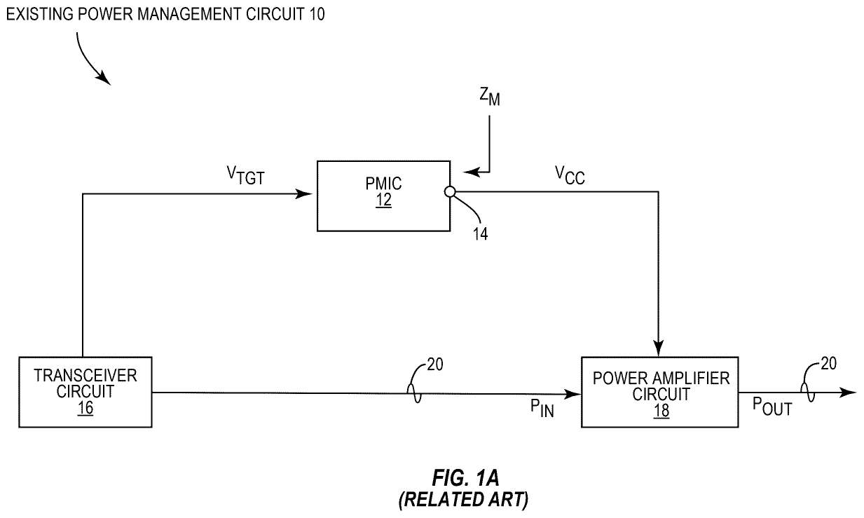

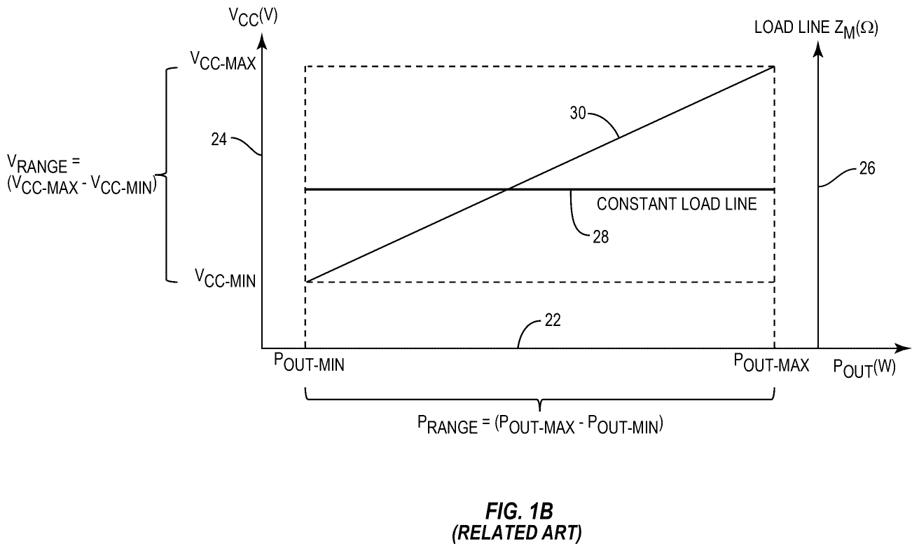

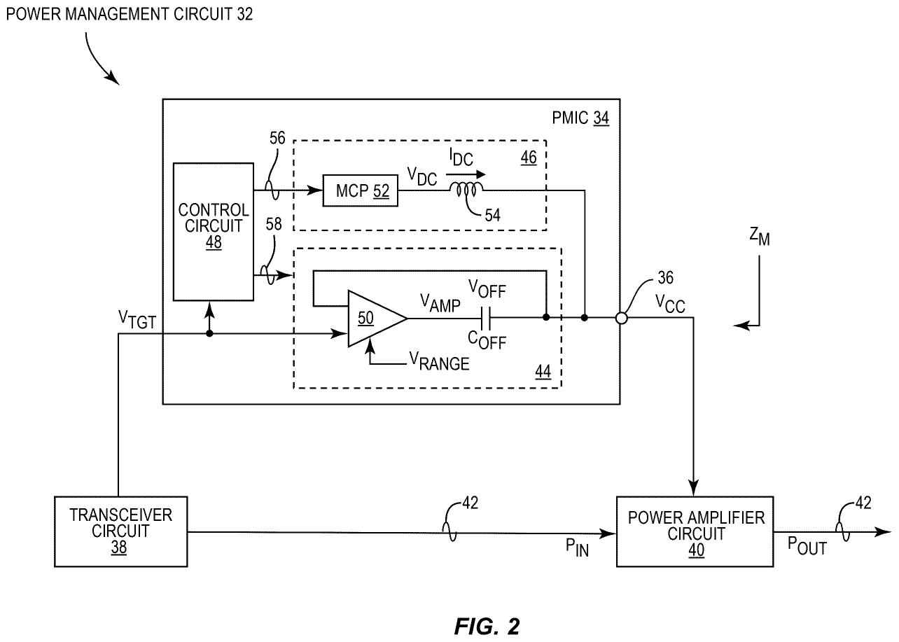

Before discussing the power management circuit of the present disclosure, starting at FIG. 2, a brief discussion of an existing power management circuit is first provided with reference to FIGS. 1A and 1B to help understand the technical problem to be solved herein.

FIG. 1A is a schematic diagram of an exemplary existing power management circuit 10 wherein a PMIC 12 can generate a modulated voltage V_{CC} (e.g., an envelope tracking voltage) in accordance with a modulated target voltage V_{TGT}. More specifically, the PMIC 12 is configured to generate the modulated voltage V_{CC} at a voltage output 14.

Herein, the existing power management circuit 10 also includes a transceiver circuit 16 and a power amplifier circuit 18. Specifically, the transceiver circuit 16 is configured to generate an RF signal 20 and the modulated target voltage V_{TGT} that tracks an input power P_{IN} and/or an output power P_{OUT} of the RF signal 20, whereas the power amplifier circuit 18 is configured to amplify the RF signal 20 from the input power P_{IN} to the output power P_{OUT} based on the modulated voltage V_{CC}. In an embodiment, the power amplifier circuit 18 can be configured to present a load line impedance Z_{M} at the voltage output 14.

FIG. 1B is a diagram providing an exemplary illustration as to how the existing power management circuit 10 of FIG. 1A is operable to generate the modulated voltage V_{CC} across a peak-to-peak range P_{RANGE} of the RF signal 20. Common elements between FIGS. 1A and 1B are shown therein with common element numbers and will not be re-described herein.

The plot illustrated herein includes a horizontal axis 22, a first vertical axis 24, and a second vertical axis 26. Specifically, the horizontal axis 22 indicates the output power P_{OUT} of the RF signal 20, the first vertical axis 24 indicates the modulated voltage V_{CC} at the voltage output 14, and the second vertical axis 26 indicates the load line impedance Z_{M} seen at the voltage output 14. In context of the present disclosure, the peak-to-peak power range P_{RANGE} of the RF signal 20 is defined as a difference between a maximum output power P_{OUT-MAX} and a minimum output power P_{OUT-MIN} of the RF signal 20 (P_{RANGE}=P_{OUT-MAX}−P_{OUT-MIN}). In the existing power management circuit 10, the power amplifier circuit 18 is configured to operate in a compression mode, wherein the load line impedance Z_{M} (as illustrated in line 28) is maintained constant and the output power P_{OUT} of the RF signal 20 is driven primarily by the modulated voltage V_{CC} (as illustrated in line 30).

Herein, the PMIC 12 is configured to generate the modulated voltage V_{CC} in a voltage range V_{RANGE} that is required for amplifying the RF signal 20 across the peak-to-peak power range P_{RANGE}. Specifically, the modulated voltage V_{CC} is equal to a difference between a maximum voltage V_{CC-MAX} and a minimum voltage V_{CC-MIN} (V_{RANGE}=V_{CC-MAX}−V_{CC-MIN}). The maximum voltage V_{CC-MAX} is the modulated voltage V_{CC} required for amplifying the RF signal 20 to the maximum voltage P_{OUT-MAX}, whereas the minimum voltage V_{CC-MIN} is the modulated voltage V_{CC} required for amplifying the RF signal 20 to the minimum voltage P_{OUT-MIN}. In a non-limiting example, the maximum voltage V_{CC-MAX} can be approximately 5.5 V and the minimum voltage V_{CC-MIN} can be approximately 1.0 V. As such, the voltage range V_{RANGE} will be equal to approximately 4.5 V.

In this regard, to support the approximately 4.5 V voltage range V_{RANGE}, the PMIC 12 in FIG. 1A would need to source more alternating current at an expense of an operating efficiency drop (e.g., 0.4-1.0% operating efficiency drop for each 100 mV of voltage increase inside the PMIC 12). As such, the technical problem to be solved herein is to reduce the voltage range V_{RANGE} to help improve the operating efficiency of the PMIC 12.

FIG. 2 is a schematic diagram of an exemplary power management circuit 32 wherein a PMIC 34 can be configured according to various embodiments of the present disclosure to reduce the peak-to-peak range V_{RANGE} of the modulated voltage V_{CC} in FIG. 1B at a voltage output 36 such that the power management circuit 32 can achieve an improved operating efficiency over the existing power management circuit 10 of FIG. 1A. As described in detail below, the power management circuit 32 can be configured to effectively reduce the voltage range V_{RANGE} in FIG. 1B by increasing the minimum voltage V_{CC-MIN}. As a result, the PMIC 34 will source a lesser amount of the alternating current to thereby help improve the operating efficiency of the PMIC 34.

In an embodiment, the power management circuit 32 also includes a transceiver circuit 38 and a power amplifier circuit 40. Specifically, the transceiver circuit 38 is configured to generate an RF signal 42 and a modulated target voltage V_{TGT} that tracks an input power P_{IN} and/or an output power P_{OUT} of the RF signal 42, whereas the power amplifier circuit 40 is configured to amplify the RF signal 42 from the input power P_{IN} to the output power P_{OUT} based on the modulated voltage V_{CC}. In an embodiment, the power amplifier circuit 40 can be configured to present a load line impedance Z_{M} at the voltage output 36 of the PMIC 34.

In an embodiment, the PMIC 34 can include a voltage modulation circuit 44, a current modulation circuit 46, and a control circuit 48. The voltage modulation circuit 44 can include a voltage amplifier 50 and an offset capacitor C_{OFF}. The voltage amplifier 50 is configured to generate a modulated initial voltage V_{AMP} as a function of the modulated target voltage V_{TGT} and the reduced voltage range V_{RANGE}. The offset capacitor C_{OFF} is coupled between the voltage amplifier 50 and the voltage output 36. The offset capacitor C_{OFF} can be charged by a low-frequency current I_{DC} to present an offset voltage V_{OFF} that can raise the modulated initial voltage V_{AMP} to the modulated voltage V_{CC} (V_{CC}=V_{AMP}+V_{OFF}).

In an embodiment, the current modulation circuit 46 can include a multi-level charge pump (MCP) 52 and a power inductor 54. The MCP 52, which can be a buck, a boost, or a buck-boost DC-DC voltage converter, is configured to generate a low-frequency voltage V_{DC} based on a duty cycle signal 56. The power inductor 54, in turn, can induce the low-frequency current I_{DC} based on the low-frequency voltage V_{DC}.

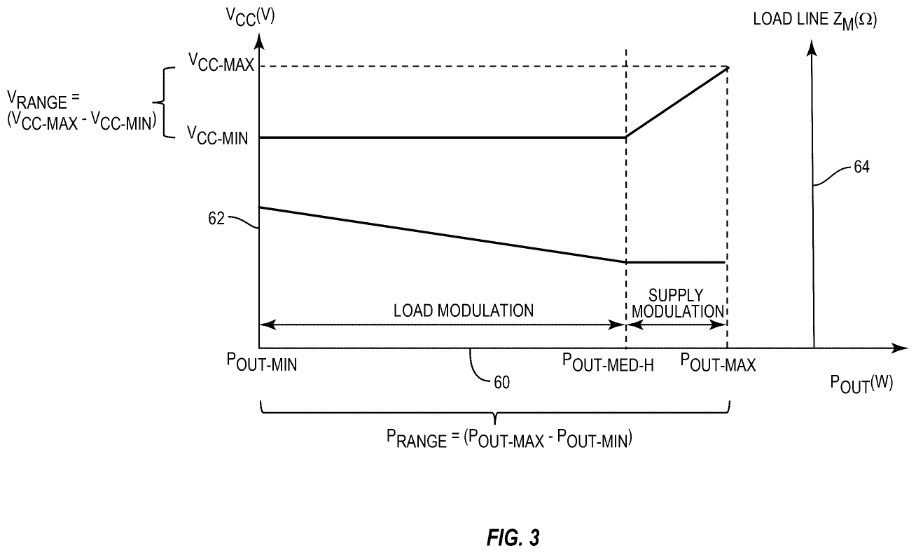

The control circuit 48, on the other hand, can be a bang-bang controller (BBC), a pulse-width modulation (PWM) controller, a field-programmable gate array (FPGA), or any other general type of controller as appropriate. As described in detailed embodiments in FIGS. 3-6 below, the control circuit 48 can control the voltage modulation circuit 44 to reduce the voltage range V_{RANGE} and, thereby, help improve the operating efficiency of the power management circuit 32.

FIGS. 3, 4, 5, and 6 are diagrams providing exemplary illustrations as to how the power management circuit 32 of FIG. 2 can be configured according to various embodiments of the present disclosure to provide the modulated voltage V_{CC} with a reduced peak-to-peak voltage range V_{RANGE} across a peak-to-peak power range P_{RANGE} of the RF signal 42. Common elements between FIGS. 2, 3, 4, 5, and 6 are shown therein with common element numbers and will not be re-described herein.

With reference to FIG. 3, the plot illustrated herein includes a horizontal axis 60, a first vertical axis 62, and a second vertical axis 64. Specifically, the horizontal axis 60 (denoted as P_{OUT}) indicates the output power P_{OUT} of the RF signal 42, the first vertical axis 62 (denoted as V_{CC}) indicates the modulated voltage V_{CC} at the voltage output 36, and the second vertical axis 64 (denoted as Load Line Z_{M}) indicates the load line impedance Z_{M} seen at the voltage output 36. Like in the existing power management circuit 10 of FIG. 1A, the power amplifier circuit 40 is also configured to operate in a compression mode and the peak-to-peak power range P_{RANGE} of the RF signal 42 is also defined as the difference between the maximum output power P_{OUT-MAX} and the minimum output power P_{OUT-MIN} (P_{RANGE}=P_{OUT-MAX}−P_{OUT-MIN}).

In an embodiment, the control circuit 48 is configured to determine a first power threshold P_{OUT-MED-H} that is lower than the max power threshold P_{OUT}. MAX of the RF signal 42. In a non-limiting example, the first power threshold P_{OUT}. MED-H can be 6 dB below the max power threshold P_{OUT-MAX} of the RF signal 42 (P_{OUT-MED-H}=P_{OUT-MAX}−6 dB).

When the instantaneous power level P_{OUT} of the RF signal 42 is higher than or equal to the first power threshold P_{OUT-MED-H} (P_{OUT}≥P_{OUT-MED-H}), the control circuit 48 is configured to cause the voltage modulation circuit 44 to generate the modulated voltage V_{CC} based on a supply modulation. Herein, the supply modulation indicates that the control circuit 48 will maintain the load line impedance Z_{M} seen at the voltage output 36 and increase the modulated voltage V_{CC}.

In contrast, when the instantaneous power level P_{OUT} of the RF signal 42 is below the first power threshold P_{OUT-MED-H} (P_{OUT}<P_{OUT-MED-H}), the control circuit 48 is configured to cause the voltage modulation circuit 44 to generate the modulated voltage V_{CC} based on a load modulation. Herein, the load modulation indicates that the control circuit 48 will reduce the load line impedance Z_{M} seen at the voltage output 36 and maintain the modulated voltage V_{CC} at the minimum voltage V_{CC-MIN}.

As illustrated in FIG. 3, the voltage modulation circuit 44 essentially raises the minimum voltage V_{CC-MIN} (e.g., from 1.0 V to approximately 2.5 V) simply by applying the load modulation below the first power threshold P_{OUT-MED}. H. As a result, if the maximum voltage V_{CC-MAX} is maintained at 5.5 V, the reduced voltage range V_{RANGE} will be reduced from approximately 4.5 V in FIG. 1A to approximately 3.0 V herein. As a result, the voltage amplifier 50 will source a lesser amount of the alternating current and, accordingly, operate with a higher operating efficiency.

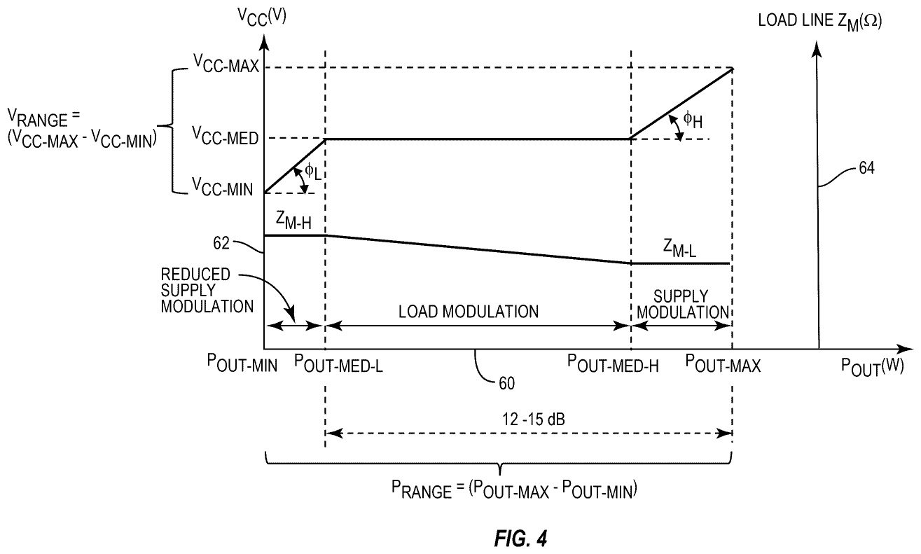

In some cases, it may be difficult to do an ideal load modulation in the power management circuit 32 if the output power P_{OUT} of the RF signal 42 increases by more than two-times (2×) over a power range of, for example, 6 dB. In this regard, as illustrated next in FIGS. 4, 5, and 6 below, it is possible to further define a second power threshold P_{OUT-MED-L}, which is lower than the first power threshold P_{OUT-MED-H} (P_{OUT-MED-L}<P_{OUT-MED-H}) but can be greater than or equal to a minimum power threshold P_{OUT-MIN} (P_{OUT-MED-L}≥ P_{OUT-MIN}). In a non-limiting example, the second power threshold P_{OUT-MED-L} can be approximately 12 dB below the max power threshold P_{OUT-MAX} of the RF signal 42 (P_{OUT-MED-L}=P_{OUT-MAX}−12 dB). Notably, the voltage range V_{RANGE} in FIGS. 4, 5, and 6 will be somewhat larger than the reduced voltage range V_{RANGE} in FIG. 3. Nevertheless, the voltage ranges V_{RANGE} in FIGS. 4, 5, and 6 are smaller than the voltage range V_{RANGE} in FIG. 1B to achieve the efficiency improvement over the existing power management circuit 10.

With reference to FIG. 4, the control circuit 48 may further define the second power threshold P_{OUT-MED-L} that is lower than the first power threshold P_{OUT-MED-H} of the RF signal 42 but higher than the minimum power threshold P_{OUT-MIN} of the RF signal 42. Specifically, the control circuit 48 can cause the voltage modulation circuit 44 to increase the modulated voltage V_{CC} from a medium voltage level V_{CC-MED} toward a maximum voltage level V_{CC-MAX} based on the supply modulation when the power level P_{OUT} of the RF signal 42 is higher than or equal to the first power threshold P_{OUT-MED-H} (P_{OUT}≥ P_{OUT-MED-H}). When the power level P_{OUT} of the RF signal 42 is lower than the second power threshold P_{OUT-MED-L} (P_{OUT}<P_{OUT-MED-L}), the control circuit 48 can cause the voltage modulation circuit 44 to increase the modulated voltage V_{CC} from a minimum voltage level V_{CC-MIN} toward the medium voltage level V_{CC-MED} based on a reduced supply modulation. Otherwise, when the power level P_{OUT} of the RF signal 42 is higher than or equal to the second power threshold P_{OUT-MED-L} but below the first power threshold P_{OUT-MED-H} (P_{OUT-MED-L}≤P_{OUT}<P_{OUT-MED-H}), the control circuit 48 will cause the voltage modulation circuit 44 to maintain the modulated voltage V_{CC} at the medium voltage level V_{CC-MED} based on the load modulation.

Notably, the modulated voltage V_{CC} can be increased in the supply modulation in accordance with a respective slope angle ϕ_{H}, whereas the modulated voltage V_{CC} can be increased in the reduced supply modulation in accordance with a respective slope angle ϕ_{L}. Herein, the respective slope angle ϕ_{H} and the respective slope angle ϕ_{L} can be equal to one another or different from one another. In a non-limiting example, the respective slope angle ϕ_{L} can be equal to the respective slope angle ϕ_{H}.

Herein, during the supply modulation (e.g., between the first power threshold P_{OUT-MED-H} and the maximum output power P_{OUT-MAX}) and the reduced supply modulation (e.g., between the minimum output power P_{OUT-MIN} and the second power threshold P_{OUT-MED-L}), the control circuit 48 is configured to cause the load line impedance Z_{M} to be maintained at a higher level Z_{M-H} in the reduced supply modulation than a lower level Z_{M-L} in the supply modulation. In contrast, the control circuit 48 may cause the load line impedance Z_{M} to decrease from the higher level Z_{M-H} toward the lower level Z_{M-L} in the load modulation.

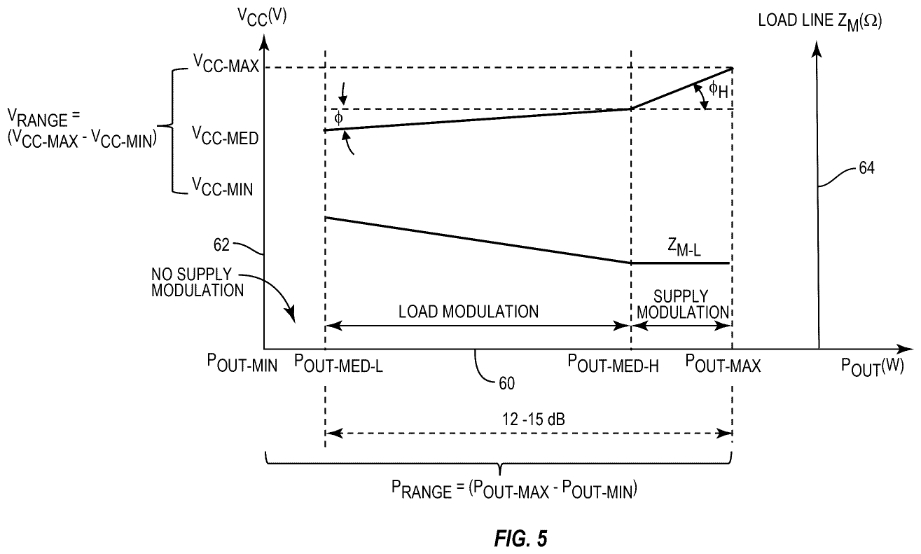

By examining an envelope probability distribution of the RF signal 42, it can be seen that the envelope probability distribution will actually span around 12-15 dB, for example, from the second power threshold P_{OUT-MED-L} toward the maximum P_{OUT-MAX}. In this regard, as illustrated in FIG. 5, it is also possible to further simplify FIG. 4 to perform no supply modulation below the second power threshold P_{OUT-MED-L}.

Specifically, the control circuit 48 is configured to cause the voltage modulation circuit 44 to increase the modulated voltage V_{CC} toward the maximum voltage level V_{CC-MAX} based on the supply modulation when the power level P_{OUT} of the RF signal 42 is higher than or equal to the first power threshold P_{OUT-MED-H} (P_{OUT}≥ P_{OUT-MED-H}). In contrast, when the power level P_{OUT} of the RF signal 42 is below the first power threshold P_{OUT-MED-H} (P_{OUT}<P_{OUT-MED-H}) but higher than or equal to the second power threshold P_{OUT-MED-L}, the control circuit 48 will cause the voltage modulation circuit 44 to perform the load modulation in combination with some degree of the supply modulation. As illustrated in FIG. 5, the modulated voltage V_{CC} has a slight angle ϕ relative to the pure horizontal line, which illustrates a result of the combination of load modulation and supply modulation. When the power level P_{OUT} of the RF signal 42 is below the second power threshold P_{OUT-MED-L}, the control circuit 48 will cause the voltage modulation circuit 44 not to perform any type of modulation.

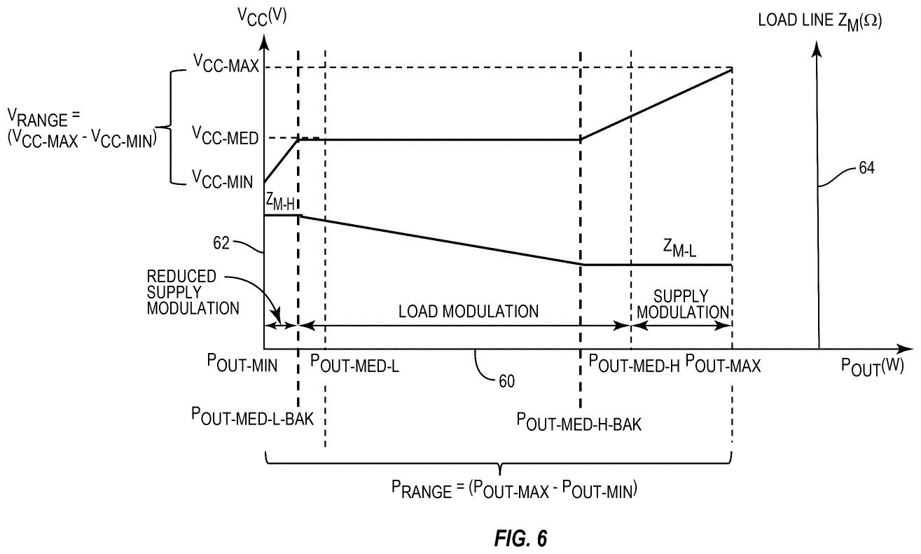

In some cases, it may be necessary to further introduce a backoff average power level to help optimize the operating efficiency of the PMIC 34 and/or the power amplifier circuit 40. In this regard, with reference to FIG. 6, the control circuit 48 can be configured to determine a first power backoff threshold P_{OUT-MED-H-BAK} that is higher than or equal to the second power threshold P_{OUT-MED-L} but lower than the first power threshold P_{OUT-MED-H} (P_{OUT-MED-L}≤P_{OUT-MED-H-BAK}<P_{OUT-MED-H}), and determine a second power backoff threshold P_{OUT-MED-L-BAK} that is lower than the second power threshold P_{OUT-MED-L} but higher than the minimum power threshold P_{OUT-MIN} (P_{OUT-MIN}≤P_{OUT-MED-L-BAK}<P_{OUT-MED-L}).

Accordingly, the control circuit 48 can be configured to cause the voltage modulation circuit 44 to increase the modulated voltage V_{CC} from the medium voltage level V_{CC-MED} toward the maximum voltage level V_{CC-MAX} based on the supply modulation when the power level P_{OUT} of the RF signal 42 is higher than or equal to the first power backoff threshold P_{OUT-MED-H-BAK}. When the power level P_{OUT} of the RF signal 42 is lower than the second power backoff threshold P_{OUT-MED-L-BAK}, the control circuit 48 can cause the voltage modulation circuit 44 to increase the modulated voltage V_{CC} from the minimum voltage level V_{CC-MIN} toward the medium voltage level V_{CC-MED} based on the reduced supply modulation. When the power level P_{OUT} of the RF signal 42 is higher than or equal to the second power backoff threshold P_{OUT-MED-L-BAK} but below the first power backoff threshold P_{OUT-MED-H-BAK}, the control circuit 48 can cause the voltage modulation circuit 44 to maintain the modulated voltage V_{CC} at the medium voltage level V_{CC-MED} based on the load modulation.

In this regard, the control circuit 48 can cause the load line impedance Z_{M} to be maintained at the higher level Z_{M-H} in the reduced supply modulation than the lower level Z_{M-L} in the supply modulation. During the load modulation, however, the control circuit 48 can cause the load line impedance Z to decrease from the higher level Z_{M-H} toward the lower level in the load modulation Z_{M-L}. In one alternative embodiment, it may also be possible to totally ignore the first power backoff threshold P_{OUT-MED-H-BAK} and/or the second power backoff threshold P_{OUT-MED-L-BAK}.

As for the load modulation, a passive variable impedance transformer network may be utilized. The passive variable impedance transformer network may be most preferred if it is possible to find the topology that introduces smaller losses while offering the tuning and bandwidth. As an example, an input impedance Z_{M-IN} and an output impedance Z_{M-OUT} of the passive impedance transformer network may be expressed as in equation (Eq. 1) below.

$${Z}_{M - IN} = {K}^{2} / {Z}_{M - OUT} \qquad ( Eq . 1 )$$

In the equation (Eq. 1), K represents a tuning factor (a.k.a. coupling ratio) that can be tuned to change a relationship between the input impedance Z_{M-IN} and the output impedance Z_{M-OUT}. In a non-limiting example, such a passive variable impedance transformer may be based on an acoustic element(s) to perform the tunable impedance transformation.

Alternatively, an active approach may also be utilized to provide the load modulation. In a non-limiting example, the active approach uses two amplifiers coupled via an impedance inverter to provide the proper load modulation.

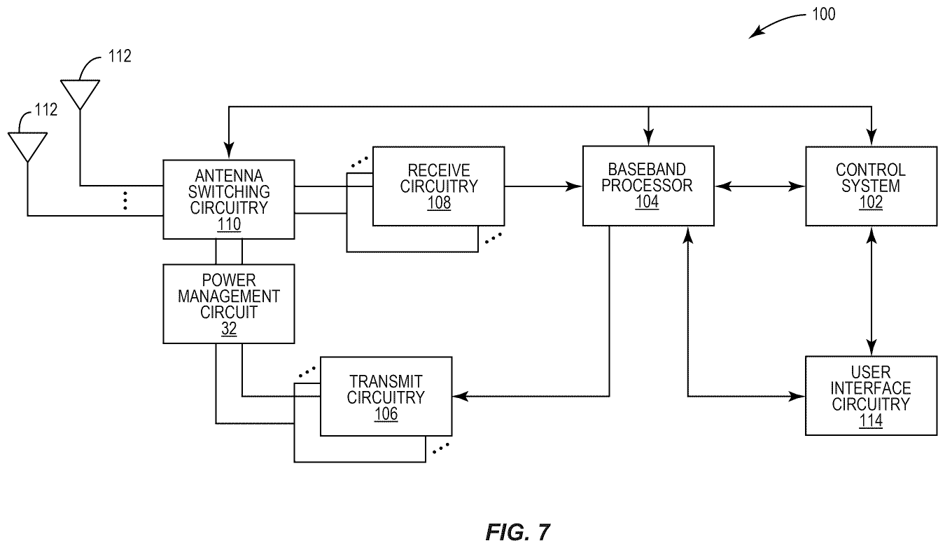

The power management circuit 32 of FIG. 2 can be provided in a communication device to support the embodiments described above. In this regard, FIG. 7 is a schematic diagram of an exemplary communication device 100 wherein the power management circuit 32 of FIG. 2 can be provided.

Herein, the communication device 100 can be any type of communication device, such as a mobile terminal, smart watch, tablet, computer, navigation device, access point, base station (e.g., eNB, gNB, etc.), and like wireless communication devices that support wireless communications, such as cellular, wireless local area network (WLAN), Ultra-wideband (UWB), Bluetooth, and near field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using an analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

In an embodiment, the transmit circuitry 106 and the receive circuitry 108 can function as a transceiver circuit. Accordingly, the power management circuit 32 can be provided between the transmit circuitry 106 and the antenna switching circuitry 110.

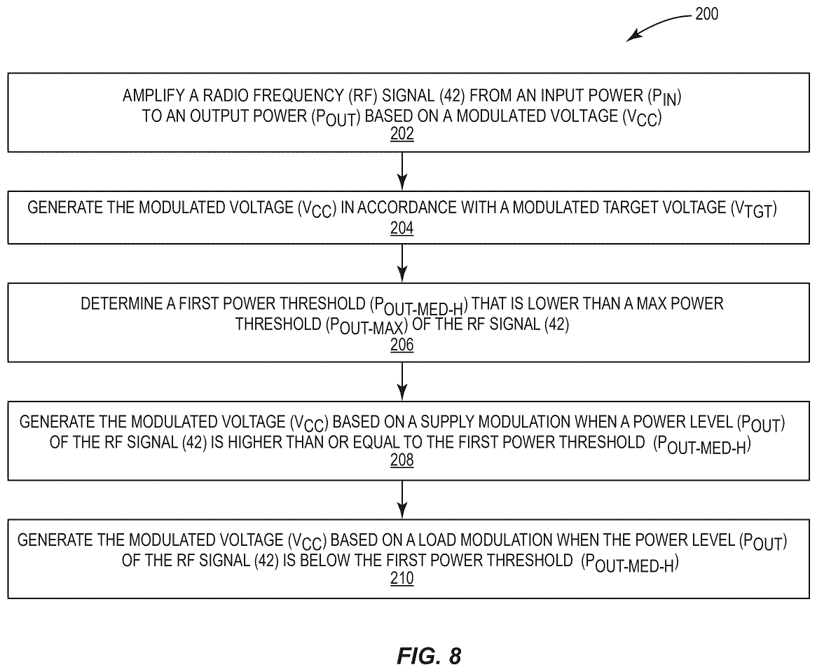

In an embodiment, the power management circuit 32 of FIG. 2 can be operated in accordance with a process. In this regard, FIG. 8 is a flowchart of an exemplary process 200 for operating the power management circuit 32 of FIG. 2.

Herein, the process 200 includes amplifying the RF signal 42 from the input power P_{IN} to the output power P_{OUT} based on a modulated voltage V_{CC} (step 202). The process 200 also includes generating the modulated voltage V_{CC} in accordance with the modulated target voltage V_{TGT} (step 204). The process 200 also includes determining the first power threshold P_{OUT-MED-H} that is lower than the max power threshold P_{OUT-MAX} of the RF signal 42 (step 206). The process 200 also includes generating the modulated voltage V_{CC} based on the supply modulation when the power level P_{OUT} of the RF signal 42 is higher than or equal to the first power threshold P_{OUT-MED-H} (step 208). The process 200 also includes generating the modulated voltage V_{CC} based on the load modulation when the power level P_{OUT} of the RF signal 42 is below the first power threshold P_{OUT-MED-H} (step 210).

Those skilled in the art will recognize improvements and modifications to the preferred embodiments of the present disclosure. All such improvements and modifications are considered within the scope of the concepts disclosed herein and the claims that follow.

What is claimed is:

1. A power management circuit comprising:
a power amplifier circuit coupled to a voltage output and configured to amplify a radio frequency (RF) signal from an input power to an output power based on a modulated voltage; and
a power management integrated circuit (PMIC) comprising:
a voltage modulation circuit configured to generate the modulated voltage at the voltage output in accordance with a modulated target voltage; and
a control circuit configured to:
determine a first power threshold that is lower than a max power threshold of the RF signal;
cause the voltage modulation circuit to generate the modulated voltage based on a supply modulation when a power level of the RF signal is higher than or equal to the first power threshold; and
cause the voltage modulation circuit to generate the modulated voltage based on a load modulation when the power level of the RF signal is below the first power threshold.

2. The power management circuit of claim 1, wherein the control circuit is further configured to:
maintain a load line impedance seen at the voltage output and increase the modulated voltage during the supply modulation; and
reduce the load line impedance seen at the voltage output and maintain the modulated voltage during the load modulation.

3. The power management circuit of claim 2, wherein the control circuit is further configured to:
maintain the load line impedance seen at the voltage output and increase the modulated voltage from a minimum voltage level toward a maximum voltage level during the supply modulation; and
reduce the load line impedance seen at the voltage output and maintain the modulated voltage at the minimum voltage level during the load modulation.

4. The power management circuit of claim 2, wherein the control circuit is further configured to:
determine a second power threshold that is lower than the first power threshold of the RF signal but higher than a minimum power threshold of the RF signal;
cause the voltage modulation circuit to increase the modulated voltage from a medium voltage level toward a maximum voltage level based on the supply modulation when the power level of the RF signal is higher than or equal to the first power threshold;
cause the voltage modulation circuit to increase the modulated voltage from a minimum voltage level toward the medium voltage level based on a reduced supply modulation when the power level of the RF signal is lower than the second power threshold; and
cause the voltage modulation circuit to maintain the modulated voltage at the medium voltage level based on the load modulation when the power level of the RF signal is higher than or equal to the second power threshold but below the first power threshold.

5. The power management circuit of claim 4, wherein the control circuit is further configured to:
cause the load line impedance to be maintained at a higher level in the reduced supply modulation than a lower level in the supply modulation; and
cause the load line impedance to decrease from the higher level toward the lower level in the load modulation.

6. The power management circuit of claim 4, wherein a respective slope angle of the reduced supply modulation is less than or equal to a respective slope angle of the supply modulation.

7. The power management circuit of claim 2, wherein the control circuit is further configured to:
determine a second power threshold that is lower than the first power threshold of the RF signal but higher than a minimum power threshold of the RF signal;
cause the voltage modulation circuit to increase the modulated voltage toward a maximum voltage level based on the supply modulation when the power level of the RF signal is higher than or equal to the first power threshold; and
cause the voltage modulation circuit to perform the load modulation and the supply modulation to thereby maintain the modulated voltage between the maximum voltage level and a minimum voltage level when the power level of the RF signal is below the first power threshold.

8. The power management circuit of claim 2, wherein the control circuit is further configured to:
determine a second power threshold that is lower than the first power threshold of the RF signal but higher than a minimum power threshold of the RF signal;
determine a first power backoff threshold higher than or equal to the second power threshold but lower than the first power threshold;
determine a second power backoff threshold lower than the second power threshold but higher than the minimum power threshold;
cause the voltage modulation circuit to increase the modulated voltage from a medium voltage level toward a maximum voltage level based on the supply modulation when the power level of the RF signal is higher than or equal to the first power backoff threshold;
cause the voltage modulation circuit to increase the modulated voltage from a minimum voltage level toward the medium voltage level based on a reduced supply modulation when the power level of the RF signal is lower than the second power backoff threshold; and
cause the voltage modulation circuit to maintain the modulated voltage at the medium voltage level based on the load modulation when the power level of the RF signal is higher than or equal to the second power backoff threshold but below the first power backoff threshold.

9. The power management circuit of claim 8, wherein the control circuit is further configured to:
cause the load line impedance to be maintained at a higher level in the reduced supply modulation than a lower level in the supply modulation; and
cause the load line impedance to decrease from the higher level toward the lower level in the load modulation.

10. A wireless device comprising a power management circuit, wherein the power management circuit comprises:
a power amplifier circuit coupled to a voltage output and configured to amplify a radio frequency (RF) signal from an input power to an output power based on a modulated voltage; and
a power management integrated circuit (PMIC) comprising:
a voltage modulation circuit configured to generate the modulated voltage at the voltage output in accordance with a modulated target voltage; and
a control circuit configured to:
determine a first power threshold that is lower than a max power threshold of the RF signal;
cause the voltage modulation circuit to generate the modulated voltage based on a supply modulation when a power level of the RF signal is higher than or equal to the first power threshold; and
cause the voltage modulation circuit to generate the modulated voltage based on a load modulation when the power level of the RF signal is below the first power threshold.

11. The wireless device of claim 10, wherein the control circuit is further configured to:
maintain a load line impedance seen at the voltage output and increase the modulated voltage during the supply modulation; and
reduce the load line impedance seen at the voltage output and maintain the modulated voltage during the load modulation.

12. The wireless device of claim 11, wherein the control circuit is further configured to:
maintain the load line impedance seen at the voltage output and increase the modulated voltage from a minimum voltage level toward a maximum voltage level during the supply modulation; and
reduce the load line impedance seen at the voltage output and maintain the modulated voltage at the minimum voltage level during the load modulation.

13. The wireless device of claim 11, wherein the control circuit is further configured to:
determine a second power threshold that is lower than the first power threshold of the RF signal but higher than a minimum power threshold of the RF signal;
cause the voltage modulation circuit to increase the modulated voltage from a medium voltage level toward a maximum voltage level based on the supply modulation when the power level of the RF signal is higher than or equal to the first power threshold;
cause the voltage modulation circuit to increase the modulated voltage from a minimum voltage level toward the medium voltage level based on a reduced supply modulation when the power level of the RF signal is lower than the second power threshold; and
cause the voltage modulation circuit to maintain the modulated voltage at the medium voltage level based on the load modulation when the power level of the RF signal is higher than or equal to the second power threshold but below the first power threshold.

14. The wireless device of claim 13, wherein the control circuit is further configured to:
cause the load line impedance to be maintained at a higher level in the reduced supply modulation than a lower level in the supply modulation; and
cause the load line impedance to decrease from the higher level toward the lower level in the load modulation.

15. The wireless device of claim 13, wherein a respective slope angle of the reduced supply modulation is equal to a respective slope angle of the supply modulation.

16. The wireless device of claim 11, wherein the control circuit is further configured to:
determine a second power threshold that is lower than the first power threshold of the RF signal but higher than a minimum power threshold of the RF signal;
cause the voltage modulation circuit to increase the modulated voltage toward a maximum voltage level based on the supply modulation when the power level of the RF signal is higher than or equal to the first power threshold; and
cause the voltage modulation circuit to perform the load modulation and the supply modulation to thereby maintain the modulated voltage between the maximum voltage level and a minimum voltage level when the power level of the RF signal is below the first power threshold.

17. The wireless device of claim 11, wherein the control circuit is further configured to:
determine a second power threshold that is lower than the first power threshold of the RF signal but higher than a minimum power threshold of the RF signal;
determine a first power backoff threshold higher than or equal to the second power threshold but lower than the first power threshold;
determine a second power backoff threshold lower than the second power threshold but higher than the minimum power threshold;
cause the voltage modulation circuit to increase the modulated voltage from a medium voltage level toward a maximum voltage level based on the supply modulation when the power level of the RF signal is higher than or equal to the first power backoff threshold;
cause the voltage modulation circuit to increase the modulated voltage from a minimum voltage level toward the medium voltage level based on a reduced supply modulation when the power level of the RF signal is lower than the second power backoff threshold; and
cause the voltage modulation circuit to maintain the modulated voltage at the medium voltage level based on the load modulation when the power level of the RF signal is higher than or equal to the second power backoff threshold but below the first power backoff threshold.

18. The wireless device of claim 17, wherein the control circuit is further configured to:
cause the load line impedance to be maintained at a higher level in the reduced supply modulation than a lower level in the supply modulation; and
cause the load line impedance to decrease from the higher level toward the lower level in the load modulation.

19. A method for operating a power management circuit with a reduced voltage range comprising:
amplifying a radio frequency (RF) signal from an input power to an output power based on a modulated voltage;
generating the modulated voltage in accordance with a modulated target voltage;
determining a first power threshold that is lower than a max power threshold of the RF signal;
generating the modulated voltage based on a supply modulation when a power level of the RF signal is higher than or equal to the first power threshold; and
generating the modulated voltage based on a load modulation when the power level of the RF signal is below the first power threshold.
